(19) United States
(12) Patent Application Publication
(10) Pub. No.: US 2026/0221942 A1
(43) Pub. Date: Jul. 30, 2026

(54) DISTRIBUTED POWER MANAGEMENT CIRCUIT

(71) Applicant: Qorvo US, Inc., Greensboro, NC (US)

(72) Inventor: Nadim Khlat, Ceret (FR)

(21) Appl. No.: 19/143,232

(22) PCT Filed: Jan. 2, 2024
(86) PCT No.: PCT/US2024/010021

§ 371 Date: Jun. 25, 2025

Related U.S. Application Data
(60) Provisional application No. 63/482,126, filed on Jan. 30, 2023.

(51) Int. Cl. H03F 1/02; H03F 1/32

(52) U.S. Cl. CPC H03F 1/0227; H03F 1/3252

(57) ABSTRACT

A distributed power management circuit is provided. The distributed power management circuit includes a main power management integrated circuit (PMIC) and a distributed PMIC separated from the main PMIC. The main PMIC is coupled to the distributed PMIC via a conductive path. In embodiments disclosed herein, the main PMIC is configured to dynamically activate or deactivate a deQ network in accordance with a modulation bandwidth of the distributed PMIC. By activating the deQ network in response to a higher modulation bandwidth, it is possible to reduce a quality factor (Q-factor) of an equivalent notch seen by the distributed PMIC to thereby improve linearity of the distributed PMIC.

### RELATED APPLICATIONS

This application claims the benefit of U.S. provisional patent application Ser. No. 63/482,126, filed on Jan. 30, 2023, the disclosure of which is hereby incorporated herein by reference in its entirety.

### FIELD OF THE DISCLOSURE

The technology of the disclosure relates generally to a distributed power management circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as fifth-generation new-radio (5G-NR) technology configured to communicate a millimeter wave (mmWave) radio frequency (RF) signal(s) in an mmWave spectrum located above 12 GHz frequency. To achieve higher data rates, a mobile communication device may employ a power amplifier(s) to increase output power of the mmWave RF signal(s) (e.g., maintaining sufficient energy per bit).

Envelope tracking (ET) and average power tracking (APT) are power management techniques designed to improve efficiency levels of power amplifiers to help reduce power consumption and thermal dissipation in a power management circuit. In a typical power management circuit, a power amplifier(s) is configured to amplify an RF signal(s) based on a time-variant voltage(s) that tracks a time-variant envelope of the RF signal(s). Understandably, the better the time-variant voltage(s) tracks the time-variant power envelope(s), the higher linearity the power amplifier(s) can achieve, particularly when the RF signal(s) is modulated across a wide modulation bandwidth (e.g., >100 MHz).

### SUMMARY

Embodiments of the disclosure relate to a distributed power management circuit. The distributed power management circuit includes a main power management integrated circuit (PMIC) and a distributed PMIC separated from the main PMIC. The main PMIC is coupled to the distributed PMIC via a conductive path. In embodiments disclosed herein, the main PMIC is configured to dynamically activate or deactivate a deQ network in accordance with a modulation bandwidth of the distributed PMIC. By activating the deQ network in response to a higher modulation bandwidth, it is possible to reduce a quality factor (Q-factor) of an equivalent notch seen by the distributed PMIC to thereby improve linearity of the distributed PMIC.

In one aspect, a distributed power management circuit is provided. The distributed power management circuit includes a distributed PMIC. The distributed PMIC is configured to generate a distributed voltage based on a distributed target voltage. The distributed power management circuit also includes a main PMIC. The main PMIC is separated from the distributed PMIC. The main PMIC includes multiple primary voltage outputs each outputting a respective one of multiple voltages and a respective one of multiple low-frequency currents to a respective one of multiple power amplifier circuits. The main PMIC also includes an auxiliary voltage output outputting a distributed low-frequency current to the distributed PMIC via a conductive path. The main PMIC also includes a deQ network. The deQ network is coupled between the auxiliary voltage output and a ground. The main PMIC also includes a control circuit. The control circuit is configured to activate the deQ network when a modulation bandwidth of the distributed voltage is higher than a threshold. The control circuit is further configured to deactivate the deQ network when the modulation bandwidth of the distributed voltage is lower than or equal to the threshold.

In another aspect, a wireless device is provided. The wireless device includes a distributed power management circuit. The distributed power management circuit includes a distributed PMIC. The distributed PMIC is configured to generate a distributed voltage based on a distributed target voltage. The distributed power management circuit also includes a main PMIC. The main PMIC is separated from the distributed PMIC. The main PMIC includes multiple primary voltage outputs each outputting a respective one of multiple voltages and a respective one of multiple low-frequency currents to a respective one of multiple power amplifier circuits. The main PMIC also includes an auxiliary voltage output outputting a distributed low-frequency current to the distributed PMIC via a conductive path. The main PMIC also includes a deQ network. The deQ network is coupled between the auxiliary voltage output and a ground. The main PMIC also includes a control circuit. The control circuit is configured to activate the deQ network when a modulation bandwidth of the distributed voltage is higher than a threshold. The control circuit is further configured to deactivate the deQ network when the modulation bandwidth of the distributed voltage is lower than or equal to the threshold.

In another aspect, a method for operating a distributed power management circuit is provided. The method includes using a distributed PMIC to generate a distributed voltage based on a distributed target voltage. The method also includes using a main PMIC separated from the distributed PMIC to output a plurality of voltages and a plurality of low-frequency currents to a plurality of power amplifier circuits, respectively, output a distributed low-frequency current to the distributed PMIC via a conductive path, activate a deQ network when a modulation bandwidth of the distributed voltage is higher than a threshold, and deactivate the deQ network when the modulation bandwidth of the distributed voltage is lower than or equal to the threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary distributed power management circuit, wherein a main power management integrated circuit (PMIC) is configured according to embodiments of the present disclosure to dynamically activate a deQ network to reduce a quality factor (Q-factor) of an equivalent notch seen by a distributed PMIC;

FIGS. 2A-2C are schematic diagrams illustrating various embodiments of the deQ network in the main PMIC in FIG. 1;

FIG. 3 is a schematic diagram of a wireless device incorporating the distributed power management circuit of FIG. 1;

FIG. 4 is a schematic diagram of an exemplary user element wherein the distributed power management circuit of FIG. 1 can be provided; and

FIG. 5 is a flowchart of an exemplary process for operating the distributed power management circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a distributed power management circuit. The distributed power management circuit includes a main power management integrated circuit (PMIC) and a distributed PMIC separated from the main PMIC. The main PMIC is coupled to the distributed PMIC via a conductive path. In embodiments disclosed herein, the main PMIC is configured to dynamically activate or deactivate a deQ network in accordance with a modulation bandwidth of the distributed PMIC. By activating the deQ network in response to a higher modulation bandwidth, it is possible to reduce a quality factor (Q-factor) of an equivalent notch seen by the distributed PMIC to thereby improve linearity of the distributed PMIC.

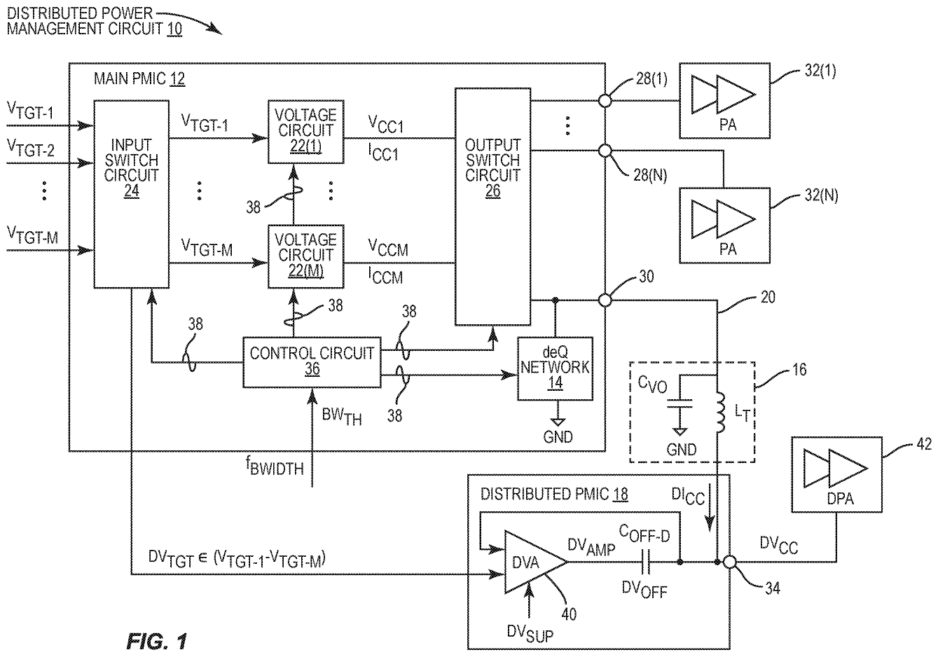

FIG. 1 is a schematic diagram of an exemplary distributed power management circuit 10, wherein a main power management integrated circuit (PMIC) 12 is configured according to embodiments of the present disclosure to dynamically activate a deQ network 14 to reduce a Q-factor of an equivalent notch 16 seen by a distributed PMIC 18. Herein, the distributed PMIC 18 is physically separated from the main PMIC 12 (e.g., in a separate die) and is coupled to the main PMIC 12 by a conductive path 20.

The main PMIC 12 includes a number of voltage circuits 22(1)-22(M). Each of the voltage circuits 22(1)-22(M) can be configured to generate a respective one of multiple voltages V_{CC1}-V_{CCM} and a respective one of multiple low-frequency currents I_{CC1}-I_{CCM} (e.g., direct currents) based on a respective one of multiple target voltages V_{TGT-1}-V_{TGT-M}.

The main PMIC 12 also includes an input switch circuit 24, an output switch circuit 26, multiple primary voltage outputs 28(1)-28(N), and at least one auxiliary voltage output 30. In an embodiment, a total number of the primary voltage outputs 28(1)-28(N) and the auxiliary voltage output 30 is equal to a total number of the voltage circuits 22(1)-22(M) (e.g., N<M). Herein, each of the primary voltage outputs 28(1)-28(N) is coupled to a respective one of multiple power amplifier circuits 32(1)-32(N) and the auxiliary voltage output 30 is coupled to a distributed voltage output 34 in the distributed PMIC 18 via the conductive path 20.

The main PMIC 12 further includes a control circuit 36, which can be a microprocessor or a field-programmable gate array (FPGA), as an example. In embodiments disclosed herein, the control circuit 36 can be configured to control the voltage circuits 22(1)-22(M), the input switch circuit 24, the output switch circuit 26, and/or the deQ network 14, either concurrently or individually, via at least one control signal 38.

Specifically, the control circuit 36 controls the input switch circuit 24 to provide the multiple target voltages V_{TGT-1}-V_{TGT-M}, which can be provided by a transceiver circuit (not shown), to the voltage circuits 22(1)-22(M). Accordingly, each of the voltage circuits 22(1)-22(M) can generate a respective one of the multiple voltages V_{CC1}-V_{CCM} and/or a respective one of the multiple low-frequency currents I_{CC1}-I_{CCM} based on a respective one of the target voltages V_{TGT-1}-V_{TGT-M}. Herein, each of the voltages V_{CC1}-V_{CCM} can be an envelope tracking (ET) voltage or an average power tracking (APT) voltage, and each of the low-frequency currents I_{CC1}-I_{CCM} can be a direct-current (DC) current.

The control circuit 36 also controls the output switch circuit 26 to couple at least one selected voltage circuit among the voltage circuits 22(1)-22(M) to the auxiliary voltage output 30 and couple the rest of the voltage circuits 22(1)-22(M) to the primary voltage outputs 28(1)-28(N). Accordingly, the control circuit 36 controls the selected voltage circuit to generate exclusively the respective one of the low-frequency currents I_{CC1}-I_{CCM}. Since the selected voltage circuit has been coupled to the auxiliary voltage output 30 that is coupled to the distributed PMIC 18, the selected voltage circuit can thus provide the respective one of the low-frequency currents I_{CC1}-I_{CCM} to the distributed PMIC 18 as a distributed low-frequency current DI_{CC} via the auxiliary voltage output 30 and the conductive path 20. The control circuit 36 further controls the input switch circuit 24 to provide the respective one of the target voltages V_{TGT-1}-V_{TGT-M}, as received by the selected voltage circuit, to the distributed PMIC 18 as a distributed target voltage DV_{TGT} (DV_{TGT}∈(V_{TGT-1}−V_{TGT-M})). In addition, the control circuit 36 controls the rest of the voltage circuits 22(1)-22(M), which are coupled to the primary voltage outputs 28(1)-28(N), to each generate the respective one of the voltages V_{CC1}-V_{CCM} and the respective one of the low-frequency currents I_{CC1}-I_{CCM}.

In a non-limiting example, the control circuit 36 first controls the input switch circuit 24 to provide the target voltages V_{TGT-1}-V_{TGT-M} to the voltage circuits 22(1)-22(M), respectively. The control circuit 36 then controls the output switch circuit 26 to couple the voltage circuit 22(M) (a.k.a. the selected voltage circuit) to the auxiliary voltage output 30 and couple the voltage circuits 22(1)-22(M−1) to the primary voltage outputs 28(1)-28(N). Accordingly, the control circuit 36 controls the input switch circuit 24 to provide the target voltage V_{TGT-M} to the distributed PMIC 18 as the distributed target voltage DV_{TGT}. In addition, the control circuit 36 controls the selected voltage circuit 28(M) to generate exclusively the respective low-frequency current I_{CCM} as the distributed low-frequency current DI_{CC}. The control circuit 36 further controls each of the remaining voltage circuits 22(1)-22(M) to generate a respective one of the voltages V_{CC1}-V_{CCM} and a respective one of the low-frequency currents I_{CC1}-I_{CCM}.

The distributed PMIC 18 includes a distributed voltage amplifier 40 (denoted as “DVA”) coupled in series to a distributed offset capacitor C_{OFF-D}. The distributed voltage amplifier 40 is configured to generate a distributed initial voltage DV_{AMP} based on the distributed target voltage DV_{TGT} and a distributed supply voltage DV_{SUP}. Notably, the distributed supply voltage DV_{SUP} may be generated inside the distributed PMIC 18 or provided by the main PMIC 12. The distributed offset capacitor C_{OFF-D} can be charged by the selected low-frequency current DI_{CC} to raise the distributed initial voltage DV_{AMP} by a distributed offset voltage DV_{OFF} to thereby generate the distributed voltage DV_{CC} at the distributed voltage output 34 (DV_{CC}=DV_{AMP}+DV_{OFF}). The distributed voltage output 34 may be coupled to a distributed power amplifier circuit 42 that operates based on the distributed voltage DV_{CC} and/or the distributed low-frequency current DI_{CC}.

Since the distributed PMIC 18 is coupled to the main PMIC 12 via the conductive path 20, the distributed PMIC 18 will see the equivalent notch 16 that is caused by an equivalent trace inductance LT of the conductive path 20 and an equivalent capacitance C_{VO} of the main PMIC 12. Herein, the capacitance C_{VO} may include an equivalent capacitance of a switch (not shown) in the output switch circuit 26 that couples the selected voltage circuit among the voltage circuits 22(1)-22(M) to the auxiliary voltage output 30. Notably, the equivalent notch 16 is shown herein to represent a collective effect of the equivalent trace inductance LT and the equivalent capacitance C_{VO}, as opposed to indicating an actual physical circuit.

The equivalent notch 16 can resonate at an equivalent series resonance frequency f_{RESONANCE}, as shown in the equation (Eq. 1) below.

$${f}_{RESONANCE} = 1 / ( 2 π \sqrt{{L}_{T} * {C}_{OV}} ) \qquad ( Eq . 1 ) V$$

As shown in the equation (Eq. 2) below, the equivalent notch 16 can also correspond to an equivalent quality factor (Q-factor) that is proportionally related to the equivalent series resonance frequency f_{RESONANCE} and a modulation bandwidth f_{BWIDTH} of the distributed PMIC 18.

$$Q - factor {=}^{def} {f}_{RESONANCE} / {f}_{BWIDTH} \qquad ( Eq . 2 )$$

When the equivalent series resonance frequency f_{RESONANCE} is close to the modulation bandwidth f_{BWIDTH}, the equivalent Q-factor will increase accordingly. In contrast, when the equivalent series resonance frequency f_{RESONANCE} is separated from the modulation bandwidth f_{BWIDTH}, the equivalent Q-factor will decrease accordingly. Understandably, when the equivalent series resonance frequency f_{RESONANCE} is close enough to the modulation bandwidth f_{BWIDTH}, the equivalent notch 16 can cause linearity degradation in the distributed power amplifier circuit 42. Since it may be difficult to completely eliminate the equivalent notch 16, it is thus desirable to reduce the equivalent Q-factor of the equivalent notch 16 as much as possible to help avoid, or at least mitigate, the linearity degradation in the distributed power amplifier circuit 42.

In this regard, the control circuit 36 is further configured according to embodiments of the present disclosure to dynamically activate or deactivate the deQ network 14 based on a threshold BW_{TH}. Notably, since the deQ network 14 is coupled in parallel to the equivalent notch 16, the deQ network 14 can thus reduce the equivalent Q-factor of the equivalent notch 16 when the deQ network 14 is activated.

Herein, the control circuit 36 is configured to activate the deQ network 14 when the modulation bandwidth f_{BWIDTH} is above the threshold BW_{TH} and deactivate the deQ network 14 otherwise. In one embodiment, the control circuit 36 may receive the modulation bandwidth f_{BWIDTH} and/or the threshold BW_{TH} from the transceiver circuit. In another embodiment, the modulation bandwidth f_{BWIDTH} and the threshold BW_{TH} may be preprogrammed into the control circuit 36.

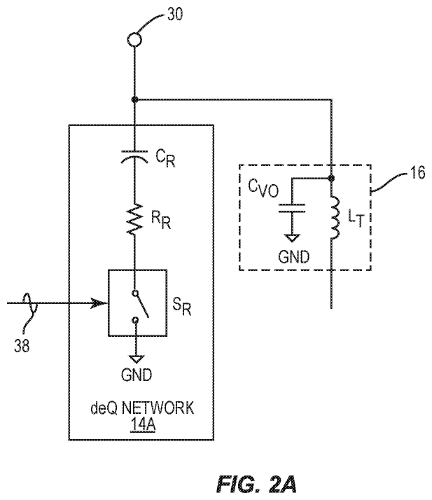

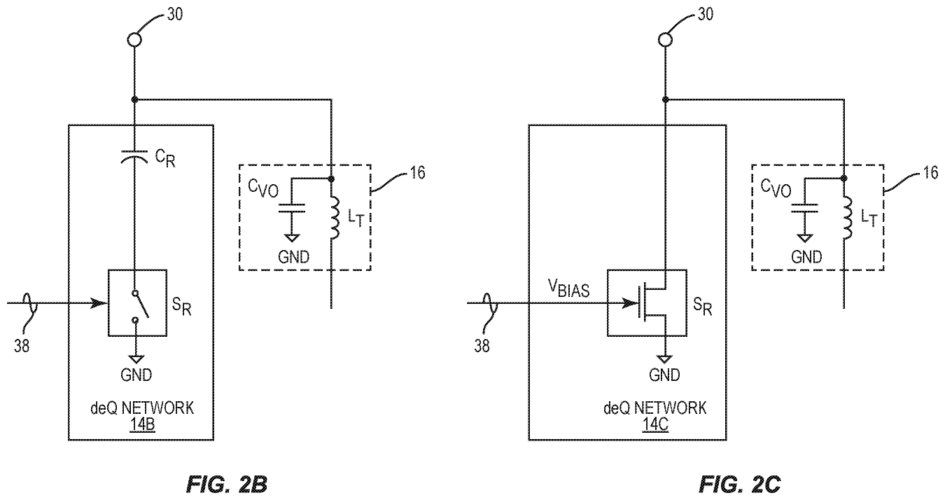

FIGS. 2A-2C are schematic diagrams illustrating the deQ network 14 configured according to various embodiments of the present disclosure. Common elements between FIGS. 1 and 2A-2C are shown therein with common element numbers and will not be re-described herein.

FIG. 2A illustrates a deQ network 14A that includes a capacitor C_{R}, a resistor R_{R}, and a switch S_{R} coupled in series between the auxiliary voltage output 30 and a ground (GND). The control circuit 36, on the other hand, is configured to close the switch S_{R} to activate the deQ network 14A and open the switch S_{R} to deactivate the deQ network 14A. Notably, since the deQ network 14A is parallel to the equivalent notch 16, the deQ network 14A can effectively reduce the equivalent Q-factor of the equivalent notch 16 when the deQ network 14A is activated.

FIG. 2B illustrates a deQ network 14B that includes the capacitor C_{R} and the switch S_{R} coupled in series between the auxiliary voltage output 30 and the GND. Herein, the switch S_{R} is so chosen to have an inherent resistance to replace the resistor R_{R}. The control circuit 36 is configured to close the switch S_{R} to activate the deQ network 14B and open the switch S_{R} to deactivate the deQ network 14B. Like the deQ network 14A in FIG. 2A, the deQ network 14B can effectively reduce the equivalent Q-factor of the equivalent notch 16 when the deQ network 14B is activated.

FIG. 2C illustrates a deQ network 14C that includes only the switch S_{R} implemented as a field-effect transistor (FET). Herein, the control circuit 36 is configured to activate or deactivate the deQ network 14C by applying the control signal 38 as a bias voltage V_{BIAS} to the FET. Herein, the control circuit 36 may control the bias voltage V_{BIAS} to increase or decrease a leakage current of the FET to thereby activate or deactivate the deQ network 14C.

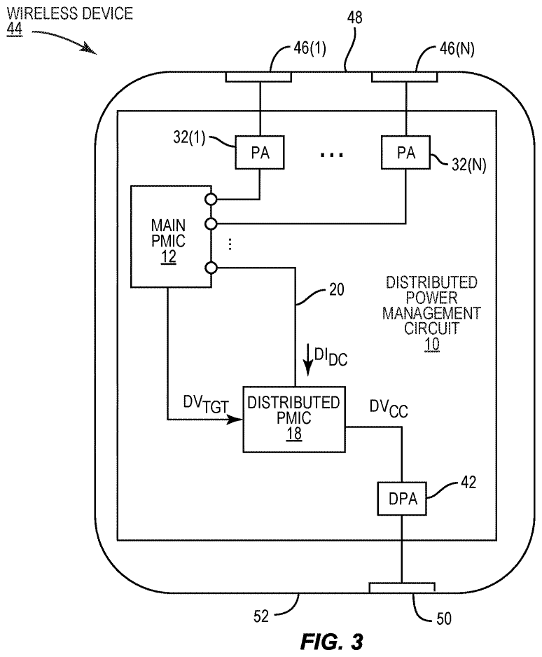

The distributed power management circuit 10 of FIG. 1 can be provided in a wireless device to enable a flexible antenna configuration. In this regard, FIG. 3 is a schematic diagram of a wireless device 44 incorporating the distributed power management circuit 10 of FIG. 1. Common elements between FIGS. 1 and 3 are shown therein with common element numbers and will not be re-described herein.

The wireless device 44 can include one or more antennas 46(1)-46(N) disposed on a first side 48 (e.g., top side) of the wireless device 44. As such, the power amplifier circuits 32(1)-32(N) can each be coupled to a respective one of the antennas 46(1)-46(N).

The wireless device 44 also includes at least one distributed antenna 50 disposed on a second side 52 (e.g., bottom side) of the wireless device 44. Accordingly, the distributed power amplifier circuit 42 can be coupled to the distributed antenna 50. As shown in FIG. 3, the second side 52 is an opposite side relative to the first side 48. By disposing the antennas 46(1)-46(N) and the distributed antenna 50 on the opposite sides of the wireless device 44, it is possible to mitigate a so-called hand-blocking effect.

In embodiments disclosed herein, the main PMIC 12 is disposed closer to each of the power amplifier circuits 32(1)-32(N) than to the distributed power amplifier circuit 42. Similarly, the distributed PMIC 18 is disposed closer to the distributed power amplifier circuit 42 than to any of the power amplifier circuits 32(1)-32(N). As a result, it is possible to reduce potential trace inductance distortion in the distributed voltage DV_{CC} to help improve efficiency and linearity of the distributed power amplifier circuit 42.

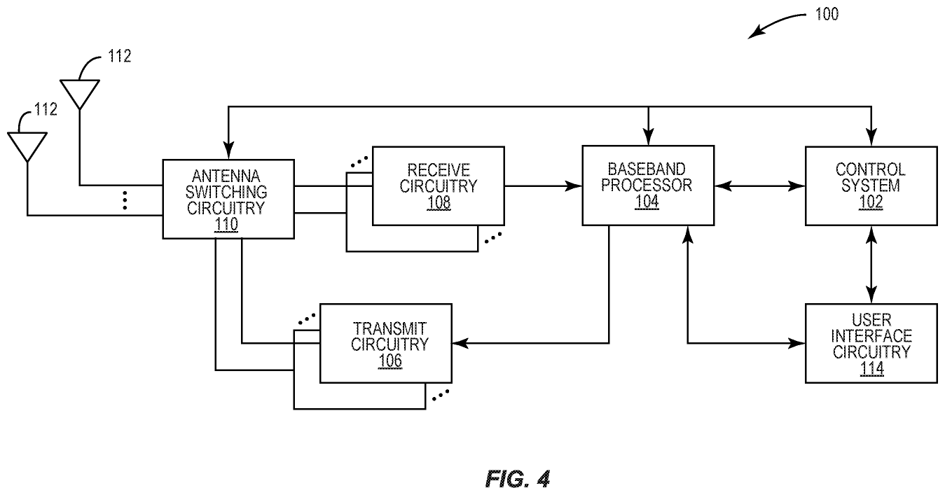

The distributed power management circuit 10 of FIG. 1 can be provided in a user element, such as the wireless device 44 of FIG. 3, to support embodiments described above. In this regard, FIG. 4 is a schematic diagram of an exemplary user element 100 wherein the distributed power management circuit 10 of FIG. 1 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

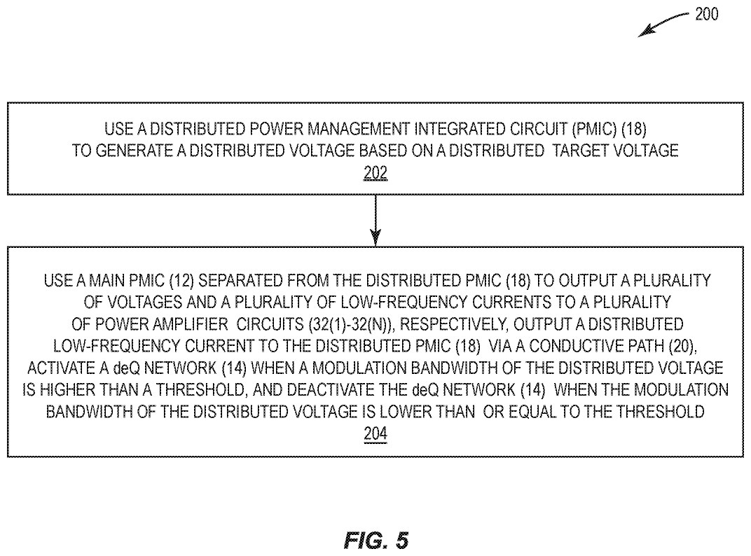

The distributed power management circuit 10 of FIG. 1 can be operated based on a process. In this regard, FIG. 5 is a flowchart of an exemplary process 200 for operating the distributed power management circuit 10 of FIG. 1.

Herein, the process 200 includes using the distributed PMIC 18 to generate a distributed voltage based on the distributed target voltage DV_{CC} (step 202). The process 200 also includes using the main PMIC 12, which is separated from the distributed PMIC 18, to output the voltages V_{CC1}-V_{CCM} and the low-frequency currents I_{CC1}-I_{CCM} to the power amplifier circuits 32(1)-32(N), respectively, output the distributed low-frequency current DI_{CC} to the distributed PMIC 18 via the conductive path 20, activate the deQ network 14 when the modulation bandwidth of the distributed voltage DV_{CC} is higher than the threshold BW_{TH}, and deactivate the deQ network 14 when the modulation bandwidth of the distributed voltage DV_{CC} is lower than or equal to the threshold BW_{TH} (step 204).

Those skilled in the art will recognize improvements and modifications to the preferred embodiments of the present disclosure. All such improvements and modifications are considered within the scope of the concepts disclosed herein and the claims that follow.

1. A distributed power management circuit comprising:
a distributed power management integrated circuit (PMIC) configured to generate a distributed voltage based on a distributed target voltage; and
a main PMIC separated from the distributed PMIC and comprising:
a plurality of primary voltage outputs each outputting a respective one of a plurality of voltages and a respective one of a plurality of low-frequency currents to a respective one of a plurality of power amplifier circuits;
an auxiliary voltage output outputting a distributed low-frequency current to the distributed PMIC via a conductive path;
a deQ network coupled between the auxiliary voltage output and a ground; and
a control circuit configured to:
activate the deQ network when a modulation bandwidth of the distributed voltage is higher than a threshold; and
deactivate the deQ network when the modulation bandwidth of the distributed voltage is lower than or equal to the threshold.

2. The distributed power management circuit of claim 1, wherein the control circuit is further configured to activate the deQ network to reduce an equivalent quality factor, Q-factor, of an equivalent notch created by an equivalent trace inductance of the conductive path and an equivalent capacitance of the main PMIC.

3. The distributed power management circuit of claim 2, wherein:
the deQ network comprises a capacitor, a resistor, and a switch coupled in series between the auxiliary voltage output and a ground; and
the control circuit is further configured to close the switch to thereby activate the deQ network and open the switch to thereby deactivate the deQ network.

4. The distributed power management circuit of claim 2, wherein:
the deQ network comprises a capacitor and a switch coupled in series between the auxiliary voltage output and a ground; and
the control circuit is further configured to close the switch to thereby activate the deQ network and open the switch to thereby deactivate the deQ network.

5. The distributed power management circuit of claim 2, wherein:
the deQ network comprises a switch comprising a field-effect transistor, (FET) coupled between the auxiliary voltage output and a ground; and
the control circuit is further configured to close the switch and increase a leakage current of the FET to thereby activate the deQ network and open the switch to thereby deactivate the deQ network.

6. The distributed power management circuit of claim 1, wherein the main PMIC further comprises:
a plurality of voltage circuits each configured to generate a respective one of the plurality of voltages and/or a respective one of the plurality of low-frequency currents based on a respective one of a plurality of target voltages; and
an output switch circuit configured to couple a selected voltage circuit among the plurality of voltage circuits to the auxiliary voltage output to output the respective one of the plurality of low-frequency currents as the distributed low-frequency current.

7. The distributed power management circuit of claim 6, wherein the control circuit is further configured to cause the respective one of the plurality of target voltages as received by the selected voltage circuit to be provided to the distributed PMIC as the distributed target voltage.

8. The distributed power management circuit of claim 6, wherein the control circuit is further configured to cause the selected voltage circuit to generate exclusively the respective one of the plurality of low-frequency currents.

9. The distributed power management circuit of claim 1, wherein the distributed PMIC comprises:
a distributed voltage amplifier configured to generate a distributed initial voltage based on the distributed target voltage and a distributed supply voltage; and
a distributed offset capacitor coupled in series to the distributed voltage amplifier and configured to raise the distributed initial voltage by a distributed offset voltage to thereby generate the distributed voltage.

10. A wireless device comprising a distributed power management circuit comprising:
a distributed power management integrated circuit, (PMIC) configured to generate a distributed voltage based on a distributed target voltage; and
a main PMIC separated from the distributed PMIC and comprising:
a plurality of primary voltage outputs each outputting a respective one of a plurality of voltages and a respective one of a plurality of low-frequency currents to a respective one of a plurality of power amplifier circuits;
an auxiliary voltage output outputting a distributed low-frequency current to the distributed PMIC via a conductive path;
a deQ network coupled between the auxiliary voltage output and a ground; and
a control circuit configured to:
activate the deQ network when a modulation bandwidth of the distributed voltage is higher than a threshold; and
deactivate the deQ network when the modulation bandwidth of the distributed voltage is lower than or equal to the threshold.

11. The wireless device of claim 10, wherein the control circuit is further configured to activate the deQ network to reduce an equivalent quality factor (Q-factor) of an equivalent notch created by an equivalent trace inductance of the conductive path and an equivalent capacitance of the main PMIC.

12. The wireless device of claim 11, wherein:
the deQ network comprises a capacitor, a resistor, and a switch coupled in series between the auxiliary voltage output and a ground; and
the control circuit is further configured to close the switch to thereby activate the deQ network and open the switch to thereby deactivate the deQ network.

13. The wireless device of claim 11, wherein:
the deQ network comprises a capacitor and a switch coupled in series between the auxiliary voltage output and a ground; and
the control circuit is further configured to close the switch to thereby activate the deQ network and open the switch to thereby deactivate the deQ network.

14. The wireless device of claim 11, wherein:
the deQ network comprises a switch comprising a field-effect transistor (FET) coupled between the auxiliary voltage output and a ground; and
the control circuit is further configured to close the switch and increase a leakage current of the FET to thereby activate the deQ network and open the switch to thereby deactivate the deQ network.

15. The wireless device of claim 10, wherein the main PMIC further comprises:
a plurality of voltage circuits each configured to generate a respective one of the plurality of voltages and/or a respective one of the plurality of low-frequency currents based on a respective one of a plurality of target voltages; and
an output switch circuit configured to couple a selected voltage circuit among the plurality of voltage circuits to the auxiliary voltage output to output the respective one of the plurality of low-frequency currents as the distributed low-frequency current.

16. The wireless device of claim 15, wherein the control circuit is further configured to cause the respective one of the plurality of target voltages as received by the selected voltage circuit to be provided to the distributed PMIC as the distributed target voltage.

17. The wireless device of claim 15, wherein the control circuit is further configured to cause the selected voltage circuit to generate exclusively the respective one of the plurality of low-frequency currents.

18. The wireless device of claim 10, wherein the distributed PMIC comprises:
a distributed voltage amplifier configured to generate a distributed initial voltage based on the distributed target voltage and a distributed supply voltage; and
a distributed offset capacitor coupled in series to the distributed voltage amplifier and configured to raise the distributed initial voltage by a distributed offset voltage to thereby generate the distributed voltage.

19. The wireless device of claim 10, further comprising:
one or more antennas disposed on a first side of the wireless device and each coupled to a respective one of the plurality of power amplifier circuits;
at least one distributed antenna disposed on a second side of the wireless device opposite the first side of the wireless device; and
at least one distributed power amplifier circuit coupled to the at least one distributed antenna.

20. The wireless device of claim 19, wherein:
the main PMIC 12 is disposed closer to each of the plurality of power amplifier circuits than to the at least one distributed power amplifier circuit; and
the distributed PMIC is disposed closer to the at least one distributed power amplifier circuit than to any of the plurality of power amplifier circuits.

21. A method for operating a distributed power management circuit comprising:
using a distributed power management integrated circuit (PMIC) to generate a distributed voltage based on a distributed target voltage; and
using a main PMIC separated from the distributed PMIC to:
output a plurality of voltages and a plurality of low-frequency currents to a plurality of power amplifier circuits, respectively;
output a distributed low-frequency current to the distributed PMIC via a conductive path;
activate a deQ network when a modulation bandwidth of the distributed voltage is higher than a threshold; and
deactivate the deQ network when the modulation bandwidth of the distributed voltage is lower than or equal to the threshold.
